(19) United States
(12) Patent Application Publication
(10) Pub. No.: US 2011/0132462 A1
(43) Pub. Date: Jun. 9, 2011

(54) MODIFIED COPPER-ZINC-TIN SEMICONDUCTOR FILMS, USES THEREOF AND RELATED METHODS

(75) Inventors: Michael Lynn Free, Salt Lake City, UT (US); Prashant Kumar Sarswat, Salt Lake City, UT (US); Ashutosh Tiwari, Sandy, UT (US); Michael Snure, Waltham, MA (US)

(73) Assignee: The University of Utah Research Foundation

(21) Appl. No.: 12/980,304

(22) Filed: Dec. 28, 2010

(51) Int. Cl. H01L 31/0264; H01L 29/12; H01L 21/36

(52) U.S. Cl. 136/265; 257/613; 438/478; 257/E29.068; 257/E31.004; 257/E21.461

(57) ABSTRACT

Provided herein are multicomponent semiconductor films having a broad range of bandgaps and charge carrier characteristics. The semiconductor films include copper, zinc, tin, at least one substitutional metal and at least one chalcogen. Substitutional metals include those capable of substituting for a portion of copper, zinc, or both in the semiconductor films. Also disclosed are methods for making the films, including single-bath electrodeposition methods, and devices incorporating the films, including photovoltaic devices.

### BACKGROUND

Despite the vast resource and great need for solar energy, solar energy provides only a small fraction of our energy requirements. Increasing solar power utilization to a level that is similar to fossil fuel use today will require new types of solar cells that are less expensive, more efficient, and more recyclable than those in current use. Improvements to solar cell efficiency will require a new generation of technology. Solar cells have inherent material properties that limit efficiency. Increasing efficiency will likely require utilization of multijunction cells, intermediate-band cells, hot carrier cells and/or spectrum conversion. The cost of solar cells is driven by a combination of materials and processing costs. Thus, lower material acquisition and manufacturing costs are needed. Power produced by solar cells must be comparable in price to power produced by fossil fuels in order for solar cells to gain a large share of the energy market. In addition, the materials used to produce solar cells must be available on a large scale in order to meet the needs for widespread solar cell use.

Copper-zinc-tin-sulfur (CZTS) films may be used as photovoltaic absorber materials in solar cells. CZTS is a direct band gap material with a bandgap of about 1.5 eV and a very high absorption coefficient. CZTS films use elements that are more widely available, cheaper, less toxic, and more recyclable than other photovoltaic absorber materials. Methods used for preparing CZTS films include atom beam sputtering, radio frequency magnetron sputtering, hybrid sputtering, thermal evaporation, photochemical deposition, spray deposition, spray hydrolysis and sulfurization of electron-beam-evaporated precursors. However, these methods have problems including expensive precursors, complicated apparatuses and, in some cases, toxic byproducts. In addition, these methods are performed at high temperatures, which can result in interdiffusion of the component elements, thereby degrading the quality of devices incorporating the films. Thus, despite the attractiveness of CZTS films, conventional CZTS films, including films prepared using these conventional methods, are unable to provide solar cells having the kind of efficiency and production costs necessary to compete with fossil fuels.

### SUMMARY

Provided herein are semiconductor films, methods for making the films and devices incorporating the films.

In one aspect, semiconductor films are provided. The semiconductor films include copper (Cu), zinc (Zn), tin (Sn), at least one substitutional metal (M) and at least one chalcogen (Ch). The one or more substitutional metals are those that are capable of substituting for a portion of copper, zinc, or both and occupying positions within the film's molecular matrix that would otherwise be occupied by copper or zinc atoms. Exemplary substitutional metals and chalcogens are disclosed. In some embodiments, the semiconductor films include copper, zinc, tin, a first substitutional metal, e.g., silver (Ag), and at least one chalcogen. In some embodiments, the semiconductor films include copper, zinc, tin, a first substitutional metal, e.g., silver (Ag), a second substitutional metal, e.g., iron (Fe) or cobalt (Co), and at least one chalcogen. Chemical formulae for exemplary semiconductor films are described below.

The structural and chemical properties of the semiconductor films are described below. Exemplary semiconductor films may be substantially amorphous or have amorphous regions and crystalline regions. Exemplary semiconductor films may have thicknesses ranging from about 0.1 μm to about 10 μm and bandgaps ranging from about 1.1 eV to about 2.5 eV. The majority charge carrier in the semiconductor films may range from n-type to p-type.

In another aspect, methods for making the semiconductor films are provided. In one embodiment, the method includes exposing a substrate to an electrolytic bath, the electrolytic bath including a copper-containing species, a zinc-containing species, a tin-containing species and at least one substitutional metal-containing species; depositing a metallic film on the substrate by electrodeposition, the metallic film including copper, zinc, tin and at least one substitutional metal; and exposing the metallic film to a source of at least one chalcogen to form the semiconductor film. Exemplary species, substrates, and electrodeposition parameters are disclosed.

In another aspect, devices including the semiconductor films are provided, including single-junction and multi-junction photovoltaic devices. In one embodiment, a photovoltaic device includes a substrate, a first semiconductor film disposed over the substrate, the first semiconductor film including copper, zinc, tin, at least one substitutional metal and at least one chalcogen; and at least one additional semiconductor film disposed over the substrate, wherein the first semiconductor film and the at least one additional semiconductor film include different majority charge carriers.

Other principal features and advantages of the invention will become apparent to those skilled in the art upon review of the following drawings, the detailed description, and the appended claims.

### BRIEF DESCRIPTION OF THE DRAWINGS

Exemplary embodiments of the invention will hereafter be described with reference to the accompanying drawings.

FIG. 1 shows the squared absorption coefficient (α²) versus photon energy (hv) for a copper-zinc-tin-sulfur (CZTS) film modified with silver (Ag).

FIG. 2 shows the Raman spectra for CZTS films modified with varying amounts of iron (Fe).

FIG. 3 shows the SEM image of the surface of a CZTS film modified with Ag and Fe.

FIG. 4 shows the EDAX spectrum of a CZTS film modified with Ag and Fe.

FIG. 5 shows the Raman spectrum of a CZTS film modified with Ag and Fe.

FIG. 6 shows the squared absorption coefficient (α²) versus photon energy (hv) for a CZTS film modified with Ag and Fe.

FIG. 7 shows the Mott-Schottky plot of a CZTS film modified with Ag and Fe.

FIG. 8 shows the Mott-Schottky plot of another CZTS film modified with Ag and Fe. The Ag content of this film is less than the Ag content of the film shown in FIG. 7.

FIG. 9 is a schematic of a photovoltaic cell.

### DETAILED DESCRIPTION

Provided herein are semiconductor films, methods for making the films, and devices incorporating the films.

Certain aspects of the invention are based, at least in part, on the inventors' findings that some portion of the copper, zinc, or both of conventional copper-zinc-tin-sulfur (CZTS) films may be substituted with certain metals to provide modified CZTS semiconductor films having a broader range of bandgaps and different majority charge carrier characteristics compared to the conventional films. Preparation of these multicomponent semiconductor films is achieved by the methods disclosed herein, including single-bath electrodeposition. Compared to conventional techniques for making copper-zinc-tin-sulfur films, electrodeposition is more cost-effective and more readily adaptable to large-scale commercial production. Moreover, electrodeposition affords control over film composition, structure, morphology, and light-absorbing properties without the problems associated with the use of high temperature synthesis methods. The semiconductor films disclosed herein may be used in a variety of devices, including photovoltaic devices. The broad range of bandgaps and different majority charge carrier characteristics of the disclosed semiconductor films provides photovoltaic devices exhibiting greater spectral range and more efficient light collection.

The term “modified” is used throughout the application with respect to copper-zinc-tin-sulfur (CZTS) films, copper-zinc-tin films, and the like. As further described below, by “modified,” it is meant that some portion of the copper, zinc, or both within the films has been substituted with certain metals. Thus, in the modified films, the stoichiometric factors of at least the copper and zinc may deviate from the stoichiometric factors within a conventional CZTS film (Cu₂ZnSnS₄). Specific, exemplary stoichiometric factors are provided below.

### Semiconductor Films

The disclosed semiconductor films include copper (Cu), zinc (Zn), tin (Sn), at least one substitutional metal (M) and at least one chalcogen (Ch). The one or more substitutional metals are those that are capable of substituting for a portion of copper, zinc, or both and occupying positions within the film's molecular matrix that would otherwise be occupied by copper or zinc atoms. A variety of substitutional metals may be used. Suitable substitutional metals may include those which possess similar valence characteristics to copper or zinc. For example, a suitable substitutional metal may include a metal that tends to form a similar oxidation state to copper or zinc. Exemplary substitutional metals include silver (Ag), iron (Fe), cobalt (Co), manganese (Mn) and calcium (Ca).

In some embodiments, the semiconductor films include copper, zinc, tin, a first substitutional metal and at least one chalcogen. The first substitutional metal may be any of those disclosed above. In other embodiments, the semiconductor films include copper, zinc, tin, a first substitutional metal, a second substitutional metal and at least one chalcogen. The first substitutional metal may substitute for a portion of copper and the second substitutional metal may substitute for a portion of zinc. In some such embodiments, the first substitutional metal is Ag and the second substitutional metal is Fe or Co.

Certain of the disclosed semiconductor films may be distinguished from doped semiconductor films, which incorporate only small concentrations of certain impurity elements into the films. As further discussed below, the disclosed semiconductor films may include significantly larger concentrations of substitutional metals than the typical concentration of impurity elements found in doped semiconductor films.

The disclosed semiconductor films include at least one chalcogen. A variety of chalcogens may be used, including sulfur and selenium. Combinations of chalcogens may also be used. In some embodiments, the semiconductor films include sulfur.

The disclosed semiconductor films may be characterized by a number of properties. For example, the semiconductor films may be characterized by the atomic/molecular structure of the films. In general, the films are mixtures of the elements disclosed above. In some embodiments, the films may be characterized as substantially homogeneous mixtures of the disclosed elements, by which it is meant that the elements of the film are distributed substantially homogeneously throughout the film, although different regions of the film may not necessarily have perfectly identical compositions. In some embodiments, the films may be characterized as alloys. In some embodiments, the films may be characterized as substantially amorphous, by which it is meant that the elements of the film exhibit substantially no long-range order, although some regions of the film may exhibit some order. In other embodiments, the films may be characterized as including one or more crystalline phases. In still other embodiments, the films may be characterized as having regions which are substantially amorphous and regions which are crystalline.

The disclosed semiconductor films may be characterized by their thickness. The thickness of the semiconductor films may vary. The methods disclosed herein are capable of providing thin semiconductor films. In some embodiments, the semiconductor films have a thickness of not more than about 100 μm. In other embodiments, the semiconductor films have a thickness of not more than about 50 μm, 20 μm, 10 μm, or 5 μm. This includes semiconductor films having a thickness ranging from about 0.1 μm to 10 μm, from about 0.1 μm to 5 μm, from about 0.5 μm to 3 μm, or from about 1 μm to 3 μm.

The disclosed semiconductor films may be characterized by their light absorbing properties, including their bandgaps. In some embodiments, the semiconductor films are characterized by a bandgap of about 1 eV or higher. In other embodiments, the semiconductor films have a bandgap of about 1.1 eV or higher, 1.3 eV, 1.5 eV, 1.7 eV, 1.9 eV, 2.1 eV, 2.3 eV, or 2.5 eV or higher. This includes semiconductor films having a bandgap ranging from about 1.1 eV to 2.5 eV.

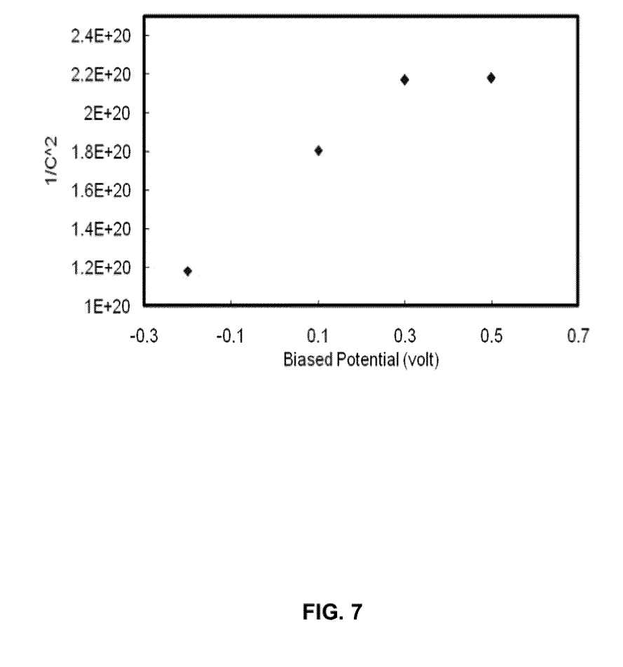

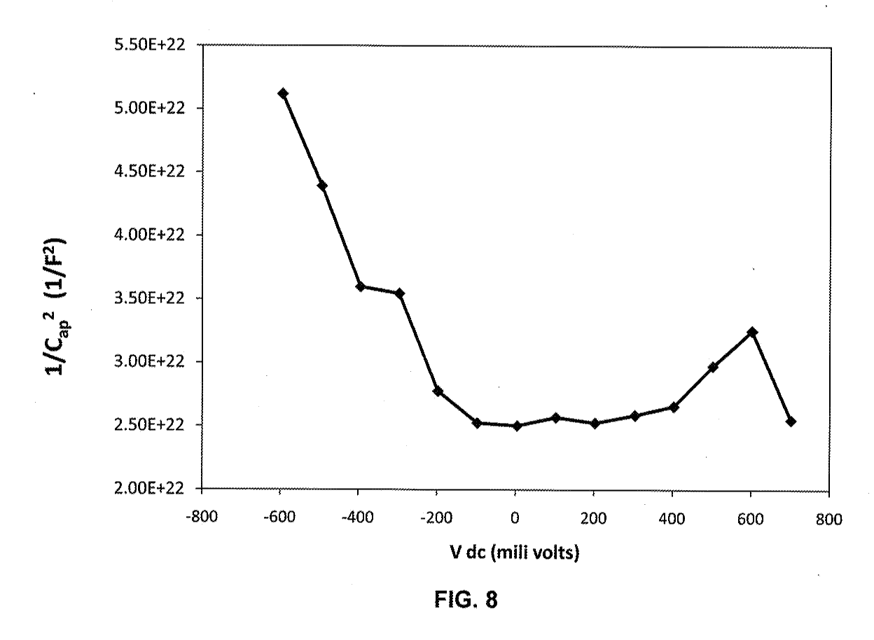

The disclosed semiconductor films may be characterized by the type of majority carrier in the film. In some embodiments, the semiconductor film includes n-type carriers and may be characterized as an n-type semiconductor film. In other embodiments, the semiconductor film includes p-type carriers and may be characterized as a p-type semiconductor film. The charge carrier characteristics of the disclosed semiconductor films may be controlled, at least in part, by the choice of substitutional metal and the amount of the substitutional metal in the film. By way of example only, a semiconductor film including silver as a substitutional metal may be varied from p-type to n-type by adjusting the amount of silver in the semiconductor film. Smaller amounts of silver provide p-type semiconductor films and greater amounts of silver provide n-type semiconductor films. This effect is shown in FIGS. 7 and 8 and is further discussed in the examples below.

The surface morphology of the disclosed semiconductor films may vary. Surface roughness may be controlled, at least in part, by the addition of certain additives and the use of certain complexing agents during film formation as further discussed in the methods section and examples below. In some embodiments, a surface of the disclosed semiconductor films is smooth as characterized by known surface analytical techniques, such as scanning electron microscopy (SEM). In such embodiments, the average vertical height between the highest and lowest features in the film is no more than about 100 nm. This includes embodiments in which the average vertical height between the highest and lowest figures is no more than about 90 nm, 80 nm, 70 nm, 60 nm, 50 nm, 40 nm, 30 nm, 20 nm, or 10 nm.

Similarly, for those semiconductor films having crystalline regions, the grain size in these regions may vary. Grain size may be controlled, at least in part, by the annealing temperature as further discussed in the methods section and examples below. In general, high annealing temperatures provide large and interconnected grains and low annealing temperatures provide smaller grains. In addition, annealing temperature may be adjusted to provide uniformity of crystalline phase.

The disclosed semiconductor films may be characterized by chemical formulae. In some embodiments, the semiconductor film may be characterized by the chemical formula Cuₐ(M₁)_{b}Zn_{c}Snₑ(Ch₁)_{f}(Ch₂)_{g}, wherein a ranges from about 0.01 to 2.00, b ranges from about 0.01 to 2.00, c ranges from about 0.15 to 1.40, e ranges from about 0.5 to 1.5, f ranges from about 0 to 4.0, g ranges from about 0 to 4.0 and further wherein the sum of a, b, c and e is about 4 and the sum of f and g is about 4. In this formula, M₁ represents a substitutional metal that is capable of substituting for a portion of copper in the film and Ch₁ and Ch₂ represent different chalcogens. Suitable substitutional metals and chalcogens are disclosed above. A variety of subranges within these ranges are possible. By way of example only, b may range from about 0.01 to 1.50, 0.01 to 1.00, 0.01 to 0.50, 0.01 to 0.10, 0.10 to 2.00, 0.50 to 2.00, 1.00 to 2.00, or 1.50 to 2.00. In some embodiments, f ranges from about 0.5 to 4.0 and g ranges from about 0.5 to 4.0. In some embodiments, M₁ is Ag. In some embodiments, M₁ is Ag, Ch₁ is sulfur, and g is 0.

In other embodiments, the semiconductor film may be characterized by the chemical formula CuₐZn_{c}(M₂)_{d}Snₑ(Ch₁)_{f}(Ch₂)_{g}, wherein a ranges from about 0.01 to 2.00, c ranges from about 0.15 to 1.40, d ranges from about 0.01 to 0.6, e ranges from about 0.5 to 1.5, f ranges from about 0 to 4.0, g ranges from about 0 to 4.0 and further wherein the sum of a, c, d and e is about 4 and the sum of f and g is about 4. In this formula, M₂ represents a substitutional metal that is capable of substituting for a portion of zinc in the film and Ch₁ and Ch₂ represent different chalcogens. Suitable substitutional metals and chalcogens are disclosed above. A variety of subranges within these ranges are possible. By way of example only, d may range from about 0.01 to 0.4, 0.01 to 0.2, 0.01 to 0.1, 0.1 to 0.6, 0.3 to 0.6, or 0.5 to 0.6. In some embodiments, f ranges from about 0.5 to 4.0 and g ranges from about 0.5 to 4.0. In some embodiments, M₂ is Fe or Co. In other embodiments, M₂ is Fe. In some embodiments, M₂ is Fe or Co, Ch₁ is sulfur, and g is 0. In other embodiments, M₂ is Fe, Ch₁ is sulfur, and g is 0.

In still other embodiments, the semiconductor film may be characterized by the chemical formula Cuₐ(M₁)_{b}Zn_{c}(M₂)_{d}Snₑ(Ch₁)_{f}(Ch₂)_{g}, wherein a ranges from about 0.01 to 2.00, b ranges from about 0.01 to 2.00 c ranges from about 0.15 to 1.40, d ranges from about 0.01 to 0.6, e ranges from about 0.5 to 1.5, f ranges from about 0 to 4.0, g ranges from about 0 to 4.0 and further wherein the sum of a, b, c, d and e is about 4 and the sum of f and g is about 4. In this formula, M₁, M₂, Ch₁ and Ch₂ are as described above. Suitable substitutional metals and chalcogens are disclosed above. A variety of subranges within these ranges are possible, including those disclosed above. In some embodiments, M₁ is Ag and M₂ is Fe or Co. In other embodiments, M₁ is Ag and M₂ is Fe. In some embodiments, M₁ is Ag, M₂ is Fe or Co, Ch₁ is sulfur, and g is 0. In other embodiments, M₁ is Ag, M₂ is Fe, Ch₁ is sulfur, and g is 0.

The disclosed semiconductor films may be disposed over a variety of substrates. Suitable substrates include electrically conducting substrates such as metals, conducting oxides, or non-conducting substrates coated with metal. Exemplary substrates include steel, fluorine doped tin oxide (FTO), and molybdenum coated glass.

Certain properties of the disclosed semiconductor films, including bandgap and majority charge carrier type, may vary depending, at least in part, on the particular composition of the film and the various electronic interactions between elements in the multicomponent films. The description and examples below provide substantial guidance for the preparation of a variety of semiconductor films having different compositions, bandgaps and majority charge carrier types.

### Methods

Also provided are methods for making the semiconductor films disclosed herein. One method involves the use of single-bath electrodeposition. In a basic embodiment of the method, the method includes exposing a substrate to an electrolytic bath, the electrolytic bath including a copper-containing species, a zinc-containing species, a tin-containing species and at least one substitutional metal-containing species; depositing a metallic film on the substrate by electrodeposition, the metallic film including copper, zinc, tin and at least one substitutional metal; and exposing the metallic film to a source of at least one chalcogen to form the semiconductor film. Any of the substitutional metals which are capable of substituting for a portion of copper, zinc, or both in the metallic film may be used. Similarly, any of the substrates and chalcogens disclosed above may be used.

A variety of copper-, zinc-, tin- and substitutional metal-containing species may be used, provided the species is capable of releasing the metal ions of the species in the electrolytic bath. Water soluble salts of copper, zinc, tin and substitutional metals are suitable metal-containing species. Exemplary copper-containing species include copper (II) sulfate pentahydrate. Exemplary zinc-containing species include zinc chloride. Exemplary tin-containing species include tin chloride. Exemplary substitutional metal-containing species include silver nitrate, iron sulfate, cobalt sulfate, nickel sulfate, or nickel sulfamate.

The electrolytic bath may include a variety of other components such as complexing agents, buffers, or additives. Exemplary complexing agents include sodium pyrophosphate. Exemplary additives include gelatin, poly acrylic acid, or polyethylene glycol. These additives can affect the nucleation density in the electrocrystallization process and may be used to adjust the surface roughness of the electrodeposited semiconductor films.

The concentrations of the components in the electrolytic bath may be varied to provide semiconductor films having the compositions and properties disclosed herein. Suitable concentration ranges for the components include: about 0.005 to 0.2 M copper-containing species; about 0.01 to 0.15 M zinc-containing species; about 0.02 to 0.05 M tin-containing species; about 0.0001 to 0.1 M substitutional metal-containing species; about 0.1 to 0.4 M complexing agent; and about 0.0001 to 0.1 M additive. Specific, exemplary concentrations are provided in certain of the examples below.

As discussed above, the methods involve depositing a metallic film by electrodeposition. In electrodeposition, the substrate and an anode are exposed to the electrolytic bath and an electric current is flowed between the substrate and anode. The electrodeposition parameters may be varied to provide semiconductor films having the compositions and properties disclosed herein. Electrodeposition parameters include voltage, which may range from about 1.1 to 2.0 V; temperature, which may range from about 20 to 90° C.; and deposition time, which may range from about 5 seconds to 30 minutes. Specific, exemplary electrodeposition parameters are provided in the examples below.

As discussed above, the methods involve exposing the metallic films formed during electrodeposition to a source of at least one chalcogen to provide the disclosed semiconductor films. Chalcogens, including sulfur, selenium, or combinations thereof, may be incorporated into the metallic films using known methods such as those described in U.S. Pat. Pub. No. 20090205714. For example, after electrodeposition of the metallic films, the metallic film may be exposed to elemental sulfur under the appropriate conditions. The examples below describe the sulfurization of metallic films using elemental sulfur at high temperatures. The time and temperature of the sulfurization process may vary. Suitable temperatures range from about 250° C. to 800° C. and suitable times range from about 30 to 300 minutes. Alternatively, chalcogens may be incorporated to the metallic films during electrodeposition by including chalcogen-containing species in the electrolytic bath. Suitable chalcogen-containing species are found in U.S. Pat. Pub. No. 20090205714.

Another method for forming the disclosed semiconductor films involves the use of spin-coating. In a basic embodiment of the method, the method includes exposing a substrate to a solution, the solution including a copper-containing species, a zinc-containing species, a tin-containing species and at least one substitutional metal-containing species; forming a metallic film on the substrate by spin-coating, the metallic film including copper, zinc, tin and at least one substitutional metal; and exposing the metallic film to a source of at least one chalcogen to form the semiconductor film. Any of the substitutional metals which are capable of substituting for a portion of copper, zinc, or both in the metallic film may be used. Similarly, any of the substrates, chalcogens and metal-containing species disclosed above may be used. This method is further described in the examples below.

### Devices

Any of the semiconductor films disclosed herein may be incorporated into a variety of devices. The semiconductor films are capable of absorbing light, including solar light, and thus, are well suited for use in photovoltaic devices, including single-junction photovoltaic devices and multi-junction photovoltaic devices. In one embodiment, a photovoltaic device includes a substrate, a first semiconductor film disposed over the substrate and at least one additional semiconductor film disposed over the substrate, wherein the semiconductor films include different majority charge carriers (e.g., the first semiconductor film is p-type and the at least one additional semiconductor film is n-type). The first semiconductor film may be any of the semiconductor films disclosed herein. The at least one additional semiconductor film may be any of the semiconductor films disclosed herein, although other types of semiconductor films are possible. In some embodiments, the first semiconductor film and the at least one additional semiconductor film are in contact and form a junction (e.g., a pn junction) in the device. In other embodiments, intervening layers (e.g., other semiconductor layers) may separate the first semiconductor film and the at least one additional semiconductor film.

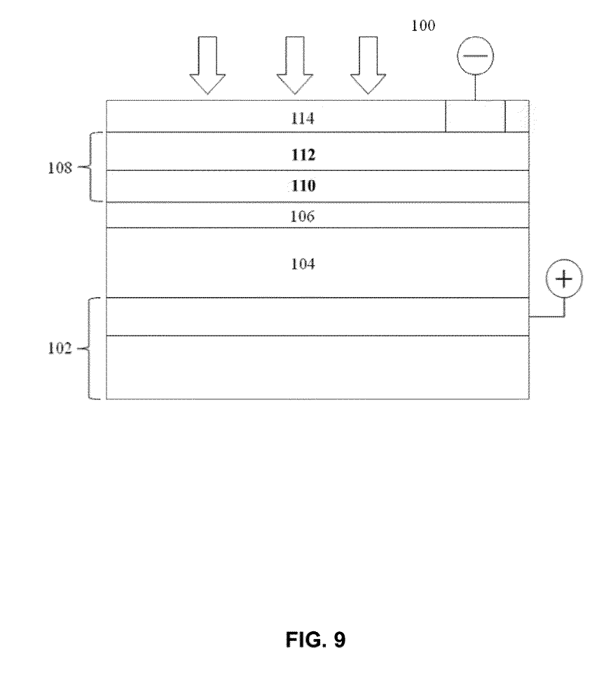

A schematic of an illustrative photovoltaic device 100 is shown in FIG. 9. The photovoltaic device includes an electrically conductive substrate 102 (e.g., a metal-coated glass substrate), a first semiconductor film 104 (e.g., any of the p-type semiconductor films disclosed herein), a second semiconductor film 106 (e.g., n-type CdS), a window layer 108 (e.g., resistive ZnO 110 and aluminum doped ZnO 112), and a contact layer 114 (e.g., MgF₂ with metallic contacts). Other photovoltaic devices, including multijunction photovoltaic devices, are possible. Any of the n-type semiconductor films disclosed herein are particularly useful in multijunction photovoltaic devices.

The semiconducting films and methods for making the films will be understood more readily by reference to the following examples, which are provided by way of illustration and are not intended to be limiting.

### EXAMPLES

### Materials and Methods

Electrodeposition of metallic films was carried out on various substrates using a potentiostat with a platinum counter electrode and a saturated calomel reference electrode. Electrowinning cells encased in a contained water jacket were used to perform the electrodeposition at a controlled temperature of 58° C. All electrochemical tests and electrodepositions were performed using EG&G 273 and Gamry Instruments PCI4/750 Potentiostats. After electrodeposition, films were rinsed in deionized water and dried with nitrogen gas. Cleaned films were sulfurized by sulfurizing in a sulfur environment as further described below.

The semiconductor films were characterized by a variety of methods including: scanning electron microscopy (SEM), Raman spectroscopy, atomic force microscopy (AFM), transmission/absorption spectroscopy, energy dispersive spectroscopy (EDS or EDAX), and electrochemical impedance spectroscopy (EIS). Cross sectional SEM was performed using a Hitachi S3000-N scanning electron microscope. Raman spectroscopy was carried out by using R 3000 QE portable Raman spectrometer (make: Raman systems). Wavelength of laser excitation for Raman measurements was 785 nm and laser power was ˜140 mW. The Raman spectrometer provides wavelength stability for measurements that is less than 1 cm⁻¹ for over a 12 hour period. Optical transmittance measurements were performed using a DU 730 UV/Visible scanning spectrophotometer in wavelength scanning mode. An atomic force microscope equipped with Nanoscope V controller (make: Veeco Instruments) was used to analyze surface topography of the films. Measurements were carried out using Si₃N₄ (silicon nitride) cantilever in contact mode.

### Example 1:

### CZTS Films Modified With Ag

Electrodeposition of copper-silver-zinc-tin films on various substrates was carried out using an electrolytic bath which included copper (II) sulfate pentahydrate, zinc chloride, silver nitrate and tin chloride. Sodium pyrophosphate was used as the complexing agent. The electrodeposition was carried out at −1.6 volts for all the elements. The concentrations of the electrolytic bath components were as follows: 0.038 M copper (II) sulfate pentahydrate, 0.080 M zinc chloride, 0.018 M tin chloride, and 0.30 M/l sodium pyrophosphate. Various concentrations of silver nitrate (0.0001 M to 0.05 M) were used to provide a number of films having different copper and silver content. Annealing was carried out at a substrate temperature of 560° C. for two hours in an argon environment with heated elemental sulfur. The annealing tube (alumina) was purged with argon for 25 minutes to displace air, prior to sulfurization. Elemental sulfur (99.9%), placed on a quartz boat, was held at a temperature of 150° C. as the sulfur source.

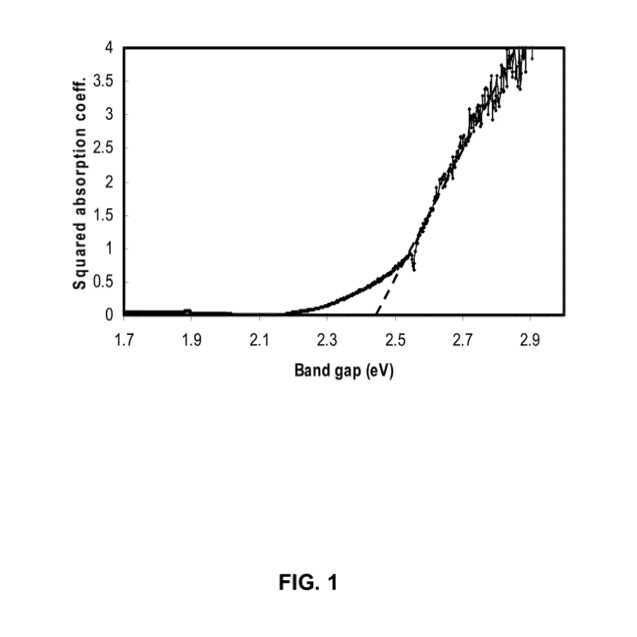

For one exemplary film prepared on a FTO substrate, the electrolytic bath included 0.038 M copper (II) sulfate pentahydrate,0.080 M zinc chloride, 0.001 M silver nitrate, 0.018 M tin chloride and 0.30 M/l sodium pyrophosphate. The film was analyzed using absorption spectroscopy. The plot of α² (α=absorption coefficient) as a function of incident photon energy provided in FIG. 1 shows that the band gap of the film was ˜2.45 eV. Another film was prepared on a FTO substrate using an electrolytic bath including 0.038 M copper (II) sulfate pentahydrate, 0.080 M zinc chloride, 0.005 M silver nitrate, 0.018 M tin chloride, and 0.30 M/l sodium pyrophosphate. The band gap of the film was determined to be ˜2.06 eV.

### Example 2:

### CZTS Films Modified With Fe

Electrodeposition of copper-zinc-iron-tin films on various substrates was carried out using an electrolytic bath which included copper (II) sulfate pentahydrate, zinc chloride, iron sulfate and tin chloride. Sodium pyrophosphate was used as the complexing agent. The electrodeposition was carried out at −1.6 volts for all the elements. The concentrations of the electrolytic bath components were as follows: 0.038 M copper (II) sulfate pentahydrate, 0.080 M zinc chloride, 0.018 M tin chloride, and 0.30 M/l sodium pyrophosphate. Various concentrations of iron sulfate were used (0.01 M to 0.05 M) to provide films having different zinc and iron content. Annealing was carried out at a substrate temperature of 560° C. for two hours in an argon environment with heated elemental sulfur. The annealing tube (alumina) was purged with argon for 25 minutes to displace air, prior to sulfurization. Elemental sulfur (99.9%), placed on a quartz boat, was held at a temperature of 150° C. as the sulfur source.

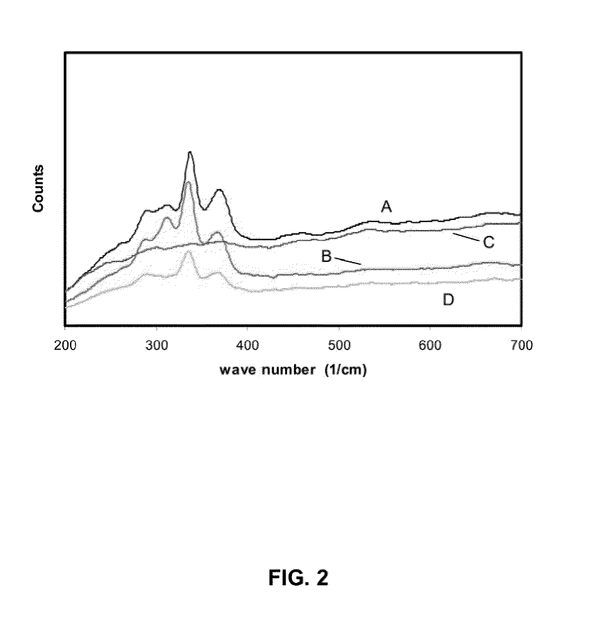

FIG. 2 shows the Raman spectra for four exemplary films. The films were prepared on FTO-coated glass substrates. The concentration of iron sulfate in the electrolyte bath was about 0.01 M (film A), 0.02 M (film B), 0.03 M (film C), or 0.05 M (film D). The peak at ˜315 cm⁻¹ in the spectra confirms the presence of iron.

### Example 3:

### CZTS Films Modified With Co

Electrodeposition of copper-zinc-cobalt-tin films on various substrates was carried out using an electrolytic bath which included copper (II) sulfate pentahydrate, zinc chloride, cobalt sulfate, tin chloride and sodium pyrophosphate as the complexing agent. The electrodeposition conditions were similar to those used in Examples 1 and 2 except that 0.02 M of cobalt sulfate was used as the substitutional metal. The annealing conditions were also similar to those used in Examples 1 and 2.

### Example 4:

### CZTS Films Modified With Ag and Fe By Electrodeposition

Electrodeposition of copper-silver-zinc-iron-tin films was carried out using an electrolytic bath which included copper (II) sulfate pentahydrate, zinc chloride, tin chloride, iron sulfate and silver nitrate. Sodium pyrophosphate was used as the complexing agent. Various concentrations of the components of the electrolytic bath were used, within the ranges of components provided in the methods section, above. Steel and transparent conducting oxide coated glass substrates were used. The electrodeposition was carried out at −1.6 volts for all the elements. Annealing was carried out at a substrate temperature of 600° C. for two hours in an argon environment with heated elemental sulfur. The annealing tube (alumina) was purged with argon for 25 minutes to displace air prior to sulfurization. Elemental sulfur (99.9%), placed on quartz boat, was held at a temperature of 150° C. as the sulfur source. Table 1 provides the range of stoichiometric factors of the modified CZTS films prepared according to this example.

TABLE 1
Stoichiometric factors of prepared
CuₐAg_{b}Zn_{c}Fe_{d}SnₑS_{f} films.

| Stoichiometric Factor | Value |
|---|---|
| a | 0.01-2.00 |
| b | 0.01-2.00 |
| c | 0.15-1.40 |
| d | 0.01-0.6 |
| e | 0.5-1.5 |
| f | 0.5-4.0 |

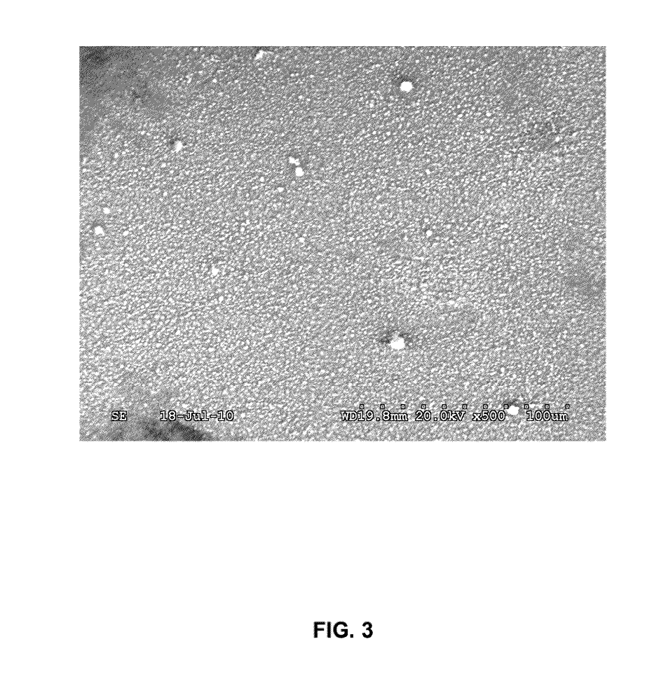

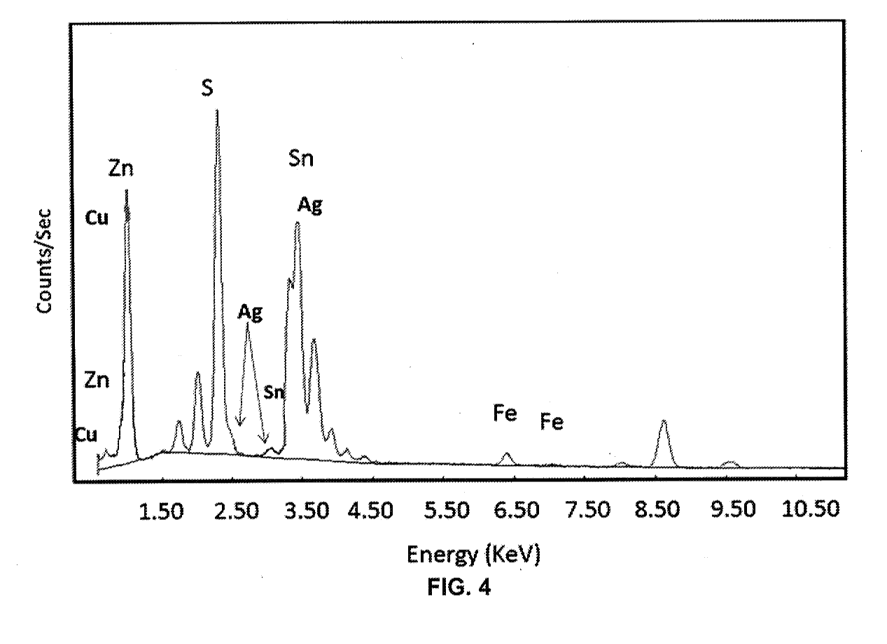

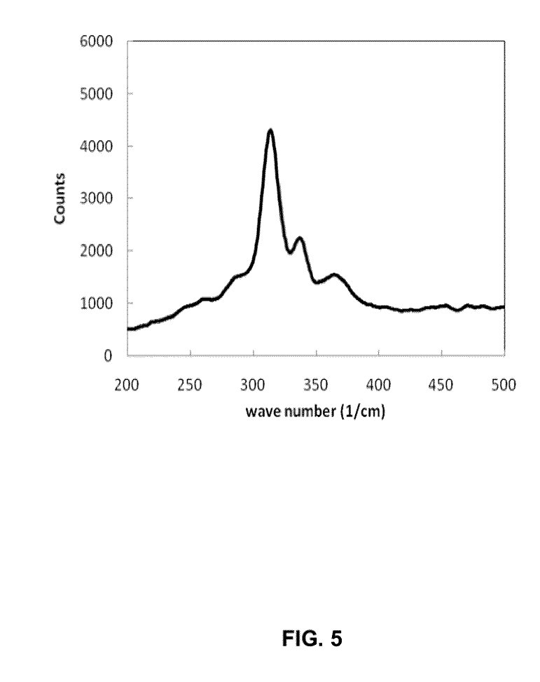

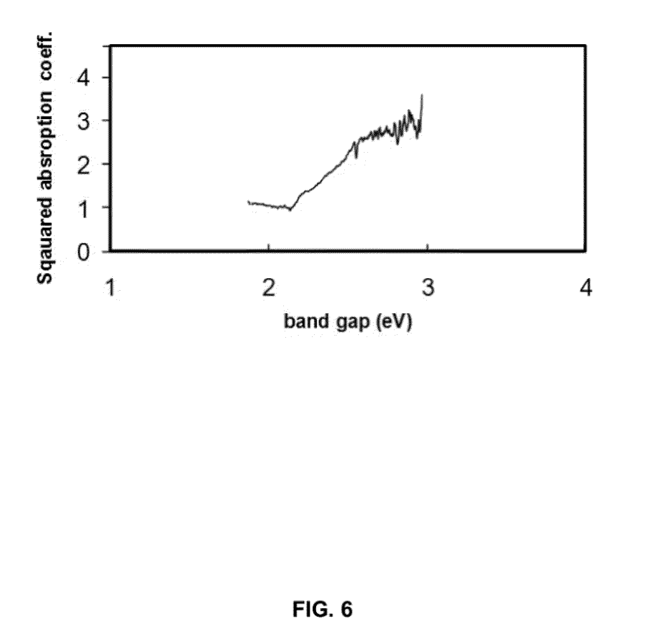

Film morphology was analyzed using SEM. FIG. 3 shows the SEM image of the surface of one exemplary film prepared on a FTO substrate. FIG. 4 shows the EDAX spectrum of the film (the y axis is counts and the x axis is energy in KeV). The pattern confirms the presence of each of the film components, Cu, Ag, Zn, Fe, Sn, and S. FIG. 5 shows the Raman spectrum of the film over the range of 200 to 500 cm⁻¹. The major peak located at ˜320 cm⁻¹ indicates that the film is Raman active and is of high optical quality. The plot of α² as a function of incident photon energy provided in FIG. 6, shows that the band gap of the film is ˜2.00 eV. FIG. 7 shows the Mott-Schottky plot of the film, indicating that the majority charge carrier of the film is n-type. This result was supported by a conventional hot probe test. Finally, the sheet resistance of the film varied between 100 k ohm and 100 M ohm, confirming the semiconducting nature of the film. FIG. 8 shows the Mott-Schottky plot of a film having a smaller amount of Ag as compared to the film of FIG. 7. The plot confirms that the film of FIG. 8 is p-type.

### Example 5:

### CZTS Films Modified With Ag and Fe By Spin-Coating

Copper-silver-zinc-iron-tin films were prepared on transparent conducting oxide coated glass substrates and soda lime glass substrates. The salts of individual metallic constituents (e.g., copper (II) sulfate pentahydrate, zinc chloride, tin chloride, iron sulfate and silver nitrate) were dissolved in monoethanolamine (MEA) and butyl alcohol as stabilizer and solvent. The concentrations of the metallic constituents used were within the range of those provided in the methods section, above. Uniform solutions were prepared by dissolving the constituents for 45 minutes. A few drops of this solution were placed on the substrate surface which was rotated (2500 rpm) for 10 seconds. The spin coated substrate was dried in air and heated at 80° C. for 3-5 minutes. The process was repeated about 4-5 times so that appropriate thickness was obtained. These substrates were further sulfurized in a sulfur environment. Sulfurization was carried out at a substrate temperature of 600° C. for two hours in an argon environment with heated elemental sulfur. The annealing tube (alumina) was purged with argon for 25 minutes to displace air prior to sulfurization. Elemental sulfur (99.9%), placed on a quartz boat, was held at a temperature of 150° C. as the sulfur source. EDAX analysis of the films revealed presence of all elements (Cu, Ag, Zn, Fe, Sn and S).

The word “illustrative” or “exemplary” is used herein to mean serving as an example, instance, or illustration. Any aspect or design described herein as “illustrative” or “exemplary” is not necessarily to be construed as preferred or advantageous over other aspects or designs. Further, for the purposes of this disclosure and unless otherwise specified, “a” or “an” means “one or more”. Still further, the use of “and” or “or” is intended to include “and/or” unless specifically indicated otherwise.

All patents, applications, references, and publications cited herein are incorporated by reference in their entirety to the same extent as if they were individually incorporated by reference.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art, all language such as “up to,” “at least,” “greater than,” “less than,” and the like includes the number recited and refers to ranges which can be subsequently broken down into subranges as discussed above. Finally, as will be understood by one skilled in the art, a range includes each individual member.

The foregoing description of illustrative embodiments of the invention have been presented for purposes of illustration and of description. It is not intended to be exhaustive or to limit the invention to the precise form disclosed, and modifications and variations are possible in light of the above teachings or may be acquired from practice of the invention. The embodiments were chosen and described in order to explain the principles of the invention and as practical applications of the invention to enable one skilled in the art to utilize the invention in various embodiments and with various modifications as suited to the particular use contemplated. It is intended that the scope of the invention be defined by the claims appended hereto and their equivalents.

What is claimed is:

1. A semiconductor film comprising copper, zinc, tin, a first substitutional metal and at least one chalcogen.

2. The semiconductor film of claim 1, wherein the first substitutional metal is selected from Ag, Fe, Co, Ni, Mn, or Ca.

3. The semiconductor film of claim 1, further comprising a second substitutional metal.

4. The semiconductor film of claim 1, further comprising a second substitutional metal, wherein the first substitutional metal and the second substitutional metal are independently selected from Ag, Fe, Co, Ni, Mn, or Ca.

5. The semiconductor film of claim 1, further comprising a second substitutional metal, wherein the first substitutional metal is Ag and the second substitutional metal is selected from Fe or Co.

6. The semiconductor film of claim 1, wherein the chalcogen is sulfur, selenium, or combinations thereof.

7. The semiconductor film of claim 1, wherein the semiconductor film is characterized by a thickness of no greater than about 10 μm.

8. The semiconductor film of claim 1, wherein the semiconductor film is characterized by the chemical formula Cuₐ(M₁)_{b}Zn_{c}Snₑ(Ch₁)_{f}(Ch₂)_{g}, wherein a ranges from about 0.01 to 2.00, b ranges from about 0.01 to 2.00, c ranges from about 0.15 to 1.40, e ranges from about 0.5 to 1.5, f ranges from about 0 to 4.0, g ranges from about 0 to 4.0 and further wherein the sum of a, b, c and e is about 4 and the sum of f and g is about 4.

9. The semiconductor film of claim 8, wherein M₁ is Ag.

10. The semiconductor film of claim 1, wherein the semiconductor film is characterized by the chemical formula CuₐZn_{c}(M₂)_{d}Snₑ(Ch₁)_{f}(Ch₂)_{g}, wherein a ranges from about 0.01 to 2.00, c ranges from about 0.15 to 1.40, d ranges from about 0.01 to 0.6, e ranges from about 0.5 to 1.5, f ranges from about 0 to 4.0, g ranges from about 0 to 4.0 and further wherein the sum of a, c, d and e is about 4 and the sum of f and g is about 4.

11. The semiconductor film of claim 10, wherein M₂ is Fe or Co.

12. The semiconductor film of claim 1, wherein the semiconductor film is characterized by the chemical formula Cuₐ(M₁)_{b}Zn_{c}(M₂)_{d}Snₑ(Ch₁)_{f}(Ch₂)_{g}, wherein a ranges from about 0.01 to 2.00, b ranges from about 0.01 to 2.00 c ranges from about 0.15 to 1.40, d ranges from about 0.01 to 0.6, e ranges from about 0.5 to 1.5, f ranges from about 0 to 4.0, g ranges from about 0 to 4.0 and further wherein the sum of a, b, c, d and e is about 4 and the sum of f and g is about 4.

13. The semiconductor film of claim 12, wherein M₁ is Ag and M₂ is Fe.

14. A photovoltaic device comprising:
(a) a substrate;
(b) a first semiconductor film disposed over the substrate, the first semiconductor film comprising copper, zinc, tin, a first substitutional metal and at least one chalcogen; and
(c) at least one additional semiconductor film disposed over the substrate,
wherein the first semiconductor film and the at least one additional semiconductor film comprise different majority charge carriers.

15. The photovoltaic device of claim 14, wherein the first substitutional metal is selected from Ag, Fe, Co, Ni, Mn, or Ca.

16. The photovoltaic device of claim 14, wherein the first semiconductor film further comprises a second substitutional metal.

17. The photovoltaic device of claim 14, wherein the first semiconductor film further comprises a second substitutional metal, and further wherein the first substitutional metal is Ag and the second substitutional metal is selected from Fe or Co.

18. A method of forming a semiconductor film, the method comprising:
(a) exposing a substrate to an electrolytic bath, the electrolytic bath comprising a copper-containing species, a zinc-containing species, a tin-containing species and a first substitutional metal-containing species;
(b) depositing a metallic film on the substrate by electrodeposition, the metallic film comprising copper, zinc, tin and a first substitutional metal; and
(c) exposing the metallic film to a source of at least one chalcogen to form the semiconductor film.

19. The method of claim 18, wherein the electrolytic bath further comprises a second substitutional metal-containing species and the metallic film further comprises a second substitutional metal.

20. The method of claim 19, wherein first substitutional metal is Ag and the second substitutional metal is Fe or Co.
